(19) United States
(12) Patent Application Publication
(10) Pub. No.: US 2006/0077636 A1
(43) Pub. Date: Apr. 13, 2006

(54) Display device usable outdoors

(76) Inventor: Sung-gi Kim, Suwon-si (KR)

Correspondence Address: STANZIONE & KIM, LLP, 919 18TH STREET, N.W., SUITE 440, WASHINGTON, DC, 20006, US

(21) Appl. No.: 11/226,244

(22) Filed: Sep. 15, 2005

(30) Foreign Application Priority Data
Oct. 12, 2004 (KR) 2004-81435

(51) Int. Cl. H05K 7/20

(52) U.S. Cl. 361/688

(57) ABSTRACT

A display device usable outdoors includes a display part to form a picture thereon, a housing to accommodate the display part and having an opening through which the display part is mounted, a protecting member installed in the opening part of the housing to protect the display part, a heat exchanger mounted within the housing to cool down an inside of the housing, and a non-reflecting coating part disposed on the protecting member to prevent a drop in brightness of the display part due to solar light. Accordingly, the display device usable outdoors prevents a drop in the brightness and a rise in temperature of the display part.

### CROSS-REFERENCE TO RELATED APPLICATIONS

This application claims the benefit of Korean Patent Application No. 2004-81435, filed on Oct. 12, 2004 in the Korean Intellectual Property Office, the disclosure of which is incorporated herein in its entirety by reference.

### BACKGROUND OF THE INVENTION

1. Field of the Invention

The present general inventive concept relates to a display device that is usable outdoors, and more particularly, to a display device that is usable outdoors and prevents a drop in brightness and a rise in temperature of a display part.

2. Description of the Related Art

Modern display devices typically use a flat panel display, such as an LCD (Liquid Crystal Display) or a PDP (Plasma Display Panel), which have a compact depth compared to an area of a part that displays a picture.

A conventional display device is generally installed in an indoor space, such as on a table, a wall, or a ceiling, and comprises a display part for forming a picture thereon and a supporting part for supporting the display part.

The display part comprises a panel part for forming the picture thereon and a back light unit for supplying light to the panel part.

With this configuration, the display device can be properly installed indoors.

However, the conventional display device has a disadvantage that its brightness drops when installed outdoors, because its brightness is only suitable for indoor use.

Also, if the conventional display device is installed outdoors, the display part can overheat due to solar heat so that inner components thereof, the panel part and other parts can be damaged.

### SUMMARY OF THE INVENTION

Accordingly, the present general inventive concept provides a display device usable outdoors to prevent a drop in brightness and a rise in temperature of a display part.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept are achieved by providing a display device usable outdoors including a display part to display an image thereon, a housing to accommodate the display part and having an opening through which the display part is mounted, a protecting member installed in the opening part of the housing to protect the display part, a heat exchanger mounted within the housing to cool down an inside of the housing, and a coating part disposed on the protecting member to maintain at least one of a brightness and a temperature of the display part.

The coating part may comprise a non-reflecting coating part to prevent a drop in the brightness of the display part due to solar light, and an insulation coating part disposed on the protecting member to prevent a rise in the temperature of the display part due to solar heat.

The housing may further comprise a main body in which the display part is mounted and a door pivotably disposed with respect to the main body and in which the heat exchanger is mounted.

The display device may further comprise a reinforcing frame disposed in the door to reinforce strength of the housing.

The protecting member may comprise a glass material.

The display part may comprise either an LCD panel or a PDP panel.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a front view illustrating a display device usable outdoors according to an embodiment of the present general inventive concept,

FIG. 2 is a side view illustrating the display device of FIG. 1,

FIG. 3 is a top view illustrating the display device of FIG. 1,

FIG. 4 is a side view illustrating a protecting member of the display device of FIG. 2.

### DETAILED DESCRIPTION OF THE PREFERRED EMBODIMENTS

Reference will now be made in detail to exemplary embodiments of the present general inventive concept, examples of which are illustrated in the accompanying drawings, wherein like reference numerals refer to like elements throughout. The embodiments are described below in order to explain the present general inventive concept by referring to the figures.

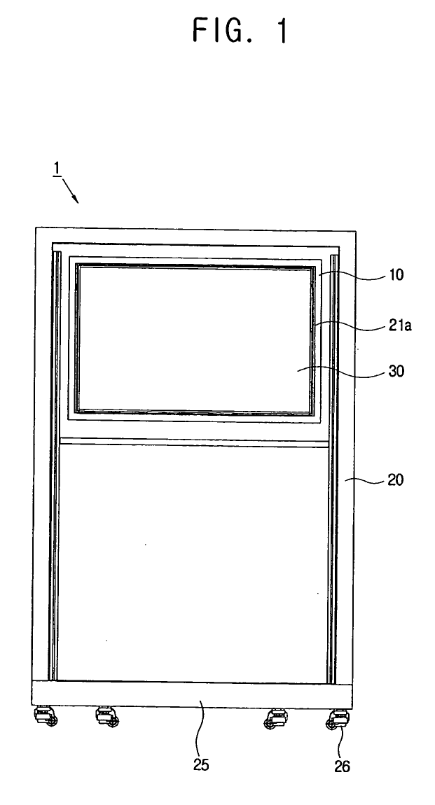

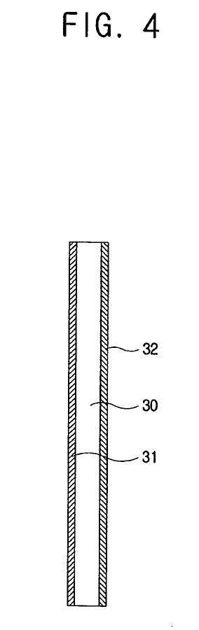

As illustrated in FIG. 1 through FIG. 4, a display device 1 that is usable outdoors according to an embodiment of the present general inventive concept comprises a display part 10 to form a picture thereon, a housing 20 to accommodate the display part 10 and formed with an opening part 21a through which the display part 10 is mounted, a protecting member 30 installed in the opening part 21a of the housing 20 to protect the display part 10, a heat exchanger 35 mounted within the housing 20 to cool down an inside of the housing 20, and a non-reflecting coating part 31 (see FIG. 4) disposed on the protecting member 30 to prevent a drop in brightness of the display part 10 due to solar light.

The display part 10 comprises a panel part (not shown) to form a picture thereon and a casing (not shown) to form an outside appearance thereof. Here, the panel part can be provided with a flat panel display such as an LCD panel, thereby reducing an installation space of the display part 10.

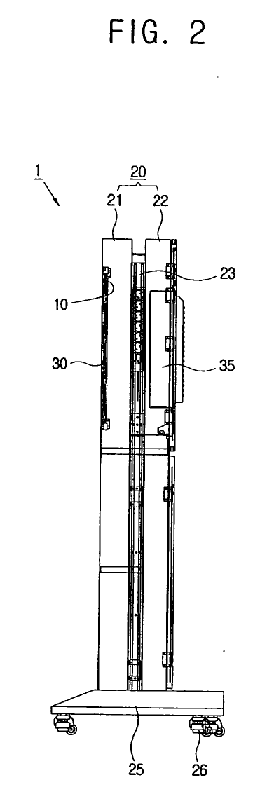

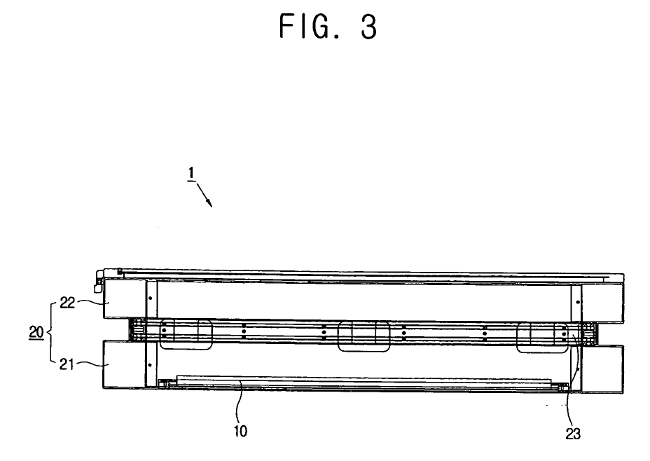

The housing 20 comprises a main body 21 (see FIGS. 2 and 3) on which the display part 10 is mounted and a door 22 pivotably disposed with respect to the main body 21, and the heat exchanger 35 is mounted on the door 22. Therefore, parts of the display device 1 mounted in the housing 20, such as the display part 10, the heat exchanger 35, etc. can be repaired with ease with the door 22 open. Also, when the door 22 is closed, the housing 20 can be kept clean and free from foreign substances such as dust and rainwater. In a lower part of the housing 20 is disposed a supporting board 25 which supports the housing 20 and has wheels 26 to move the housing 20. Aluminum material, which is corrosion resistant, may be used to form the housing 20.

In an upper part of a surface of the main body 21, the opening part 21a is formed to extend therethrough, and the protecting member 30 is mounted in the opening part 21a.

A reinforcing frame 23 is disposed on and around the door 22 to reinforce the housing 20. The reinforcing frame 23 prevents the housing 20 from being damaged due to outer shocks and from moving freely due to a strong wind. Like the housing 20, the reinforcing frame 23 may also be made of aluminum material.

Referring to FIGS. 1 and 4, the protecting member 30 is mounted in the opening part 21a of the housing 20, so that it protects the display part 10 from external damage caused by rain, wind, and the like. An insulation coating part 32 may be disposed on a rear surface of the protecting member 30 to prevent the temperature in the display part 10 from rising due to solar heat. The non-reflecting coating part 31 is disposed on a front surface of the protecting member 30 and is coated with a thin film. A film type of insulation coating part 32 may be adhered to either the front or rear surface of the protecting member 30, and the non-reflecting coating part 31 may be coated with the thin film on the surface. The protecting member 30 can be made of plastic material having high transparency such as polycarbonate (PC), acryl, etc. Alternatively, glass material may be used to form the protecting member 30, since it has a high degree of strength and is not easily scratched.

The heat exchanger 35 (see FIG. 2) is disposed within the housing 20 and keeps the display part 10 from overheating. Since the brightness of the display part 10 typically drops due to solar light when the display part 10 is installed outdoors, a back light in the display device 1 usable outdoors should be two to three times brighter than that in a display device used indoors. Heat produced by the back light may tend to cause the temperature of the display part 10 to increase. However, operation of the heat exchanger 35 can prevent the display part 10 from over heating due to heat produced by the back light. As a result, inner components of the display part 10 are not damaged. The heat exchanger 35 may comprise a fan (not shown) to send cold air to the display part 10. In addition, the heat exchanger 35 may comprise a heater (not shown) to maintain proper inner temperature of the housing 20 when outside temperature is low.

The panel part of the display part in the embodiment described above may include an LCD panel or a PDP panel. Other display panels may also be used.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A display device usable outdoors, comprising:
a display part to display an image;
a housing to accommodate the display part and having an opening part through which the display part is mounted;
a protecting member installed in the opening part of the housing to protect the display part;
a heat exchanger mounted within the housing to cool down an inside of the housing; and
a coating part disposed on the protecting member to maintain at least one of a brightness and a temperature of the display part.

2. The display device of claim 1, wherein the coating part comprises a non-reflecting coating part to prevent a drop in the brightness of the display part due to solar light.

3. The display device of claim 2, wherein the coating part further comprises an insulation coating part disposed on the protecting member to prevent a rise in the temperature of the display part due to solar heat.

4. The display device of claim 3, wherein the housing comprises a main body in which the display part is mounted and a door pivotably disposed with respect to the main body and in which the heat exchanger is mounted.

5. The display device of claim 4, further comprising:
a reinforcing frame disposed in the door to reinforce a strength of the housing.

6. The display device of claim 3, wherein the protecting member comprises glass material.

7. A display device accommodating a display part therein, comprising:
a rectangular housing having a front side and a rear side;
a rectangular opening disposed in the front side for the display part to be viewable therethrough; and
a protecting member disposed inside the rectangular opening to seal the rectangular housing and to protect the display part.

8. The display device of claim 7, further comprising:
a reinforcing frame disposed between the front side and the rear side, and the rear side is pivotable with respect to the front side to enable the housing to be pivotably opened.

9. The display device of claim 8, wherein the front side and the rear side of the rectangular housing are wider than a width of the display part.

10. The display device of claim 8, wherein at least one of the rectangular housing and the reinforcing frame comprises aluminum material.

11. The display device of claim 7, further comprising:
a support stand to support the rectangular housing and having wheels to enable the rectangular housing and the support stand to be moved.

12. The display device of claim 7, further comprising:
a temperature regulator disposed in the rear side of the rectangular housing to regulate temperature inside the rectangular housing.

13. The display device of claim 12, wherein the temperature regulator includes one or more of a cooling unit to prevent the display part from overheating, and a heating unit to prevent the display part from overcooling.

14. The display device of claim 13, wherein the cooling unit comprises a fan.

15. The display device of claim 7, wherein the protecting member comprises:
an insulation part disposed on a surface of the protecting member and to insulate an inside of the rectangular housing from an exterior; and
a coating part disposed on an outer surface of the protecting member to prevent brightness of the display part from dropping.

16. The display device of claim 7, wherein the protecting member comprises a transparent material including one of a glass material and a plastic material.

17. The display device of claim 7, wherein a back light of the display part has an outdoor brightness that is between two to three times an indoor brightness.

18. An outdoor display device, comprising:
a display housing to house a display part and having an opening to view the display part disposed in a front part thereof;
a brightness maintaining part disposed in the opening in the display housing to prevent a brightness of the display part from being affected by outdoor lighting; and
a temperature maintaining part disposed in the display housing to maintain a proper range of temperatures inside the display housing.

19. The outdoor display device of claim 18, wherein a depth of the display housing corresponds to a depth of a flat panel display part.

20. The outdoor display device of claim 18, wherein the brightness maintaining part comprises a transparent panel having a first thin film coating to insulate the inside of the display housing from an exterior and a second thin film coating to prevent reflection of solar light.

21. An outdoor display cabinet housing to accommodate a display unit, comprising:
an opening in a front portion thereof; and
a transparent protecting member mounted in the opening to insulate and protect the display unit from external forces while permitting viewing thereof.

22. The outdoor display cabinet housing of claim 21, wherein the protecting member comprises:
a non-reflecting coating part disposed on a front surface thereof; and
an insulation coating part adhered to either the front or a rear surface thereof to protect the display unit from solar heat.
